(19) United States
(12) Patent Application Publication
(10) Pub. No.: US 2015/0097471 A1
(43) Pub. Date: Apr. 9, 2015

(54) WATER RESISTANT OUTDOOR ELECTRONICS CABINET

(71) Applicant: STEVAN M. BAILEY, LAGUNA BEACH, CA (US)

(72) Inventor: STEVAN M. BAILEY, LAGUNA BEACH, CA (US)

(21) Appl. No.: 14/503,360

(22) Filed: Sep. 30, 2014

Related U.S. Application Data
(60) Provisional application No. 61/887,320, filed on Oct. 4, 2013.

(51) Int. Cl. H05K 5/06; E06B 5/00; A47B 81/00

(52) U.S. Cl. CPC H05K 5/061; A47B 81/00; E06B 5/006
USPC 312/100

(57) ABSTRACT

The present invention includes a water resistant outdoor storage cabinet for housing electronics equipment, telecommunications equipment or other water sensitive apparatus sought to be stored outdoors and protected from environmental elements such as extreme heat and cold, wind, snow weight, pest destruction and in particular water ingress. More specifically, the present invention is a double gasket system and complementary perimeter flange for water resistant outdoor storage cabinets that meet the water ingress testing requirements of NEBS GR-47-CORE by incorporating two gaskets around the perimeter of an access port in a storage cabinet and between the door and the storage cabinet.

### CROSS-REFERENCE TO RELATED APPLICATIONS

This application claims the benefit of U.S. Provisional Application No. 61/887,320, filed Oct. 4, 2013, the disclosure of which is incorporated herein by reference.

### FIELD OF THE INVENTION

The present invention relates to a water resistant gasket assembly and complementary perimeter flange to seal access ports, doors and hatches on water resistant outdoor storage cabinets designed to house and protect electronics equipment, telecommunications equipment and other water sensitive apparatus from exposure to water, dust and other detrimental elements sufficient to pass governmental regulations for such water intrusion, including GR-47.

### BACKGROUND

There are many configurations and applications of water resistant outdoor storage cabinets known in the industry for housing and protecting various sensitive electronics and telecommunications equipment. However, many rely on costly double walls or seals that must be replaced upon opening of any access door.

Embodiments of the present invention relate to protective containers for such backup power supplies, telecommunications equipment and other sensitive electronics that must be maintained outdoors in the harsh environment of its surroundings including enclosures and methods for protecting such sensitive equipment from environmental hazards. Telecommunication systems connected to power lines and telephone wires are particularly vulnerable to harsh environmental effects, which generally will occur during a natural disaster when such telecommunications are most in need of protection and reliability.

A water resistant outdoor storage cabinet is designed and constructed in an ordinary manner to be structurally adequate to endure these environmental conditions and to hold the necessary water sensitive apparatus within for which it is designed. While an outdoor storage cabinet may have several openings, holes, cutouts or other ports for entry of wires, cables, tubing, supporting equipment such as fans, etc., most of these ports can be permanently sealed in such a way that there is no ingress of water through these ports. Removable access ports are at greater vulnerability to water ingress and the present invention addresses this vulnerability.

The access port of the storage cabinet box is of primary concern for water ingress because it is not permanently sealed and must function as a door to be opened and closed with such regularity as is needed to install and maintain the equipment and apparatus within the storage cabinet. The access port allows access to the equipment and apparatus within the storage cabinet for installation, maintenance, repairs or other work necessary keep the equipment within in proper working order.

The telecommunications industry and other industries use backup power supplies or “uninterruptible power sources” (UPS's) to maintain operations when primary power sources fail or are interrupted. These UPS's are used to supply backup power to critical electrical and electronic equipment during primary power interruptions. Such backup power may also be contained within outdoor storage cabinets.

The telecommunications industry has widely adopted a set of industry standards known as the NEBS (“Network Equipment—Building System”) standards. The NEBS standards were developed by Bell Labs in the 1970's to standardize equipment that would eventually be installed in either an Incumbent Local Exchange Carrier (ILEC) or Regional Bell Operating Company (RBOC) Central Office. The NEBS standards basically describe the environment of a typical or generic RBOC Central Office. Bell Labs' intent in developing the NEBS standards was to make it easier for vendors to design and supply equipment compatible with a generic RBOC Central Office environment.

A main NEBS standard is Bellcore (now Telcordia) GR-47-CORE “Network Equipment—Building System (NEBS) Requirements provides generic criteria for water ingress resistance for telecommunications network equipment. This section defines the environmental condition that must be withstood by a particular piece of equipment to be NEBS certified. This section requires the equipment to withstand a most severe water event. GR-47-CORE.

Current approaches for protecting sensitive electronics and telecommunications equipment are enclosures that are often costly and not well suited for efficient use with standard sized telecommunications equipment and components often fail due to the lack of successful water resistance by the cabinets requiring owners to replace equipment periodically adding to the cost of maintaining a communication system. Gasket seals are often made using EPDM rubber. Unfortunately, EPDM coatings are best when the surface is flat, clean and smooth. However, due to the various penetrations through a storage cabinet, a flat, clean and smooth surface is rarely available. Moreover, application of EPDM rubber is labor intensive and costly. Similar to painting projects, application of EPDM rubber requires the time-consuming aspects of cleaning, repairing and preparing the surface for application of the material. Furthermore, EPDM is actually formulated for recreational vehicles, trailers, motor homes, commercial and residential roofs, and fishponds and fountains. It is not designed for the environments and needed reliability of sensitive telecommunications equipment and the requirements designed to ensure protection of such equipment.

Other attempts to further resist ingress of water to the interior of such storage cabinets have been through the use of thicker or stronger gaskets. But these attempts often become too bulky to allow complete and easy closing of the doors and become too expensive.

What is needed are improved equipment storage cabinets that are designed and capable of withstanding severe environmental conditions including water ingress as required by GR-47. Such cabinets should be convenient to transport to their final location by not being cumbersome or unnecessarily heavy and should be cost effective solutions to protect sensitive equipment.

Accordingly, there is a need for outdoor storage cabinets capable of resisting water ingress that comply with the NEBS GR-47-CORE environmental testing requirements. Preferably such a cabinet is adaptable to any required size of equipment storage. Such a storage cabinet solution should be efficient to construct, should occupy a minimum amount of space, should be relatively light, and should be relatively affordable compared to non-NEBS certified storage systems.

### SUMMARY

The present invention includes a water resistant outdoor storage cabinet where a storage cabinet box having an exterior face has at least one continuous perimeter flange defining an access port on the exterior face of the storage cabinet box. The perimeter flange has a protruding surface portion and an inverted surface portion. A door complementary to the access port and removably attached to the exterior face of the storage cabinet box has a gasket assembly affixed to it. The perimeter flange and the gasket assembly are configured to create a water tight seal when the door is in a closed position and the gasket assembly is in a contacting relation to the perimeter flange.

A further embodiment of the present invention includes a water resistant outdoor storage cabinet where the gasket assembly is made up of a first gasket and a second gasket where the first gasket is configured to conform to the inverted surface portion of the perimeter flange and the second gasket is configured to conform to the protruding surface portion of the perimeter flange. The first gasket may be a bubble-type gasket and the second gasket may be a flat-type gasket.

The water resistant outdoor equipment storage cabinet is further designed and capable of passing NEBS GR-47 testing.

Yet a further embodiment of the present invention includes a water resistant outdoor equipment storage cabinet where a storage cabinet box has an exterior face with an access port and a door defined by a perimeter flange configured to cover the access port. A gasket assembly is adhered to the exterior face of the storage cabinet box such that the perimeter flange and gasket assembly form a water tight seal when the door is in a closed position sufficient to pass NEBS GR-47 testing.

### BRIEF DESCRIPTION OF THE DRAWINGS

FIG. 1 illustrates a perspective view of the water resistant outdoor storage cabinet showing the storage cabinet box and door with placement of perimeter flange on the storage cabinet box and the gasket assembly on the door.

FIG. 2 shows a cross-sectional view of the water resistant outdoor storage cabinet showing the gasket assembly and perimeter flange on the door and storage cabinet box, respectively.

FIG. 3 illustrates a closer perspective of the cross-sectional view of the water resistant outdoor storage cabinet with the door in the closed position and more closely showing a locking lip extending partially into the channel of the inverted surface of the flange.

FIG. 4 illustrates a closer perspective of the cross-sectional view of the water resistant outdoor storage cabinet with the door in the closed position and more closely showing a further embodiment of the inverted surface providing only a single vertical wall forming the flange.

### DETAILED DESCRIPTION

In the following description, for purposes of explanation and not limitation, specific details are set forth in order to provide a thorough understanding of the present invention. However, it will be apparent to one skilled in the art that the present invention may be practiced in other embodiments that depart from these specific details. In other instances, detailed descriptions of well-known methods and devices are omitted so as to not obscure the description of the present invention with unnecessary detail.

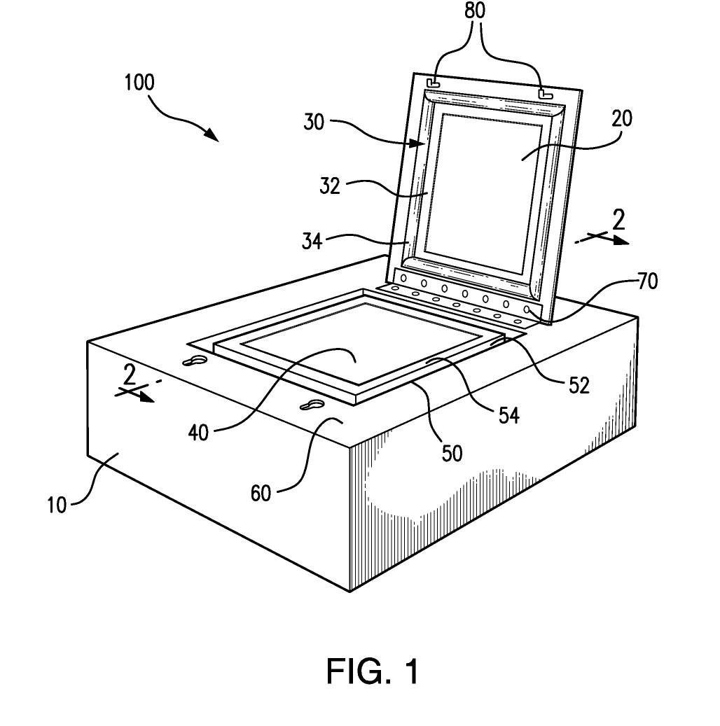

FIG. 1 shows water resistant outdoor storage cabinet 100 employing double gasket assembly 30 and perimeter flange 50 in accordance with the present invention. Except for double gasket assembly 30 and perimeter flange 50, water resistant outdoor storage cabinet 100 is constructed in a conventional manner.

Water resistant outdoor storage cabinet 100 of the present invention may be of any shape, size or dimension as needed to accommodate the electronics, telecommunications equipment or other water sensitive apparatus sought to be stored within water resistant outdoor storage cabinet 100. Water resistant outdoor storage cabinet 100 is designed to hold such water sensitive apparatus and to protect the apparatus enclosed therein from environmental elements such as extreme heat, extreme cold, wind, snow weight, pest destruction and water ingress. It is to be understood that the double gasket assembly and perimeter flange in accordance with the present invention may also be applied to water resistant outdoor storage cabinets that employ other forms of access ports and also to water resistant outdoor storage cabinet devices that do not necessarily have a provision for removable doors ports.

FIG. 1 shows water resistant outdoor storage cabinet 100 with storage cabinet box 10 having exterior surface 60 with access port 40 defined by perimeter flange 50 and covered by door 20, which is removably attached to exterior surface 60 by hinge assembly 70. Water sensitive equipment and apparatus may be located within the interior of storage cabinet box 10 and accessible through access port 40 for repair or replacement. When door 20 is in a closed position, latch 80 may restrain door 20 from opening.

Storage cabinet box 10 has at least one continuous perimeter flange 50 preferably incorporated into exterior face 60 defining access port 40. In an alternative embodiment, door 20 may have perimeter flange 50 incorporated into the perimeter face of door 20.

Storage cabinet box 10 may be fabricated of any durable material engineered to endure the requirements of the cabinet such as sheet steel or comparable durable material including fiberglass reinforced epoxy composite, or high strength aluminum.

Access port 40 provides access to the interior of storage cabinet box 10 and door 20 covers access port 40 when in a closed position. Storage cabinet box 10 should be engineered to be rigid with access port 40 in order to reduce warping or other gapping that may allow water ingress through access port 40 to the interior of storage cabinet box 10. Shapes and configurations for storage cabinet box 10 may be as desired including spherical, oblique, cubical, or other rectangular prism.

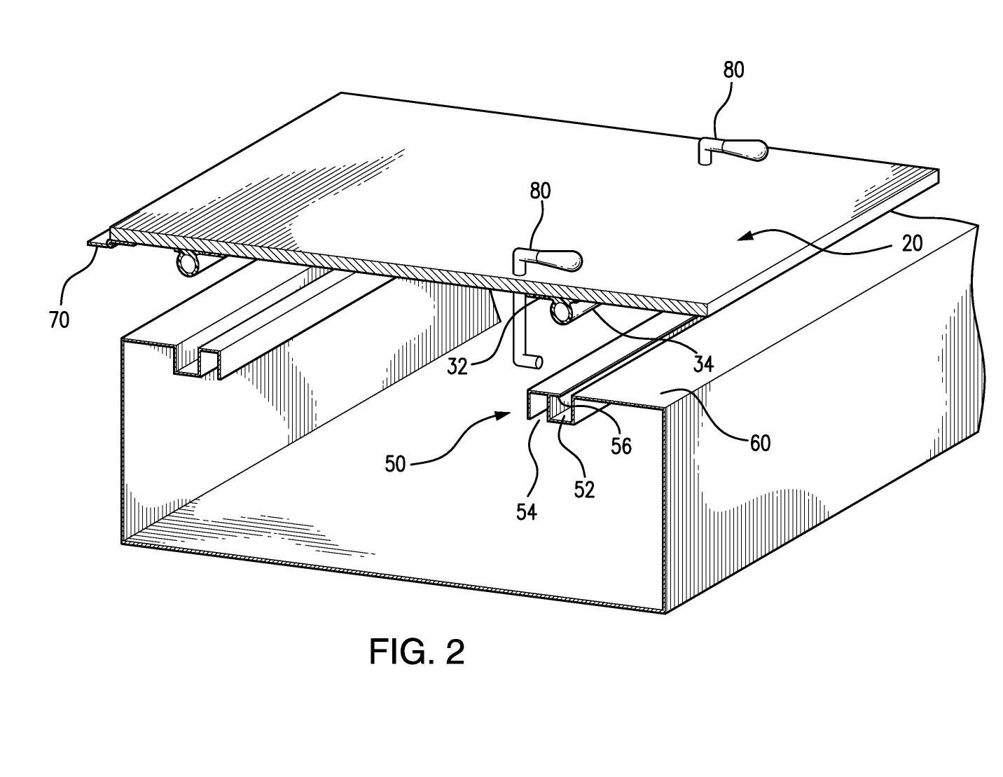

FIG. 2 shows a preferred embodiment of the present invention where the perimeter face of door 20 is fitted with double gasket assembly 30 of the present invention designed to come in contacting relation with perimeter flange 50 around access port 40 on exterior face 60 of storage cabinet box 10. In further embodiments, double gasket assembly 30 may be fitted onto exterior surface 60 around access port 40 and designed to come in contacting relation with perimeter flange 50 that would then be on door 20.

Double gasket assembly 30 of the present invention uses two types of gaskets to seal and resist ingress of water to the interior of water resistant outdoor storage cabinet 100 and is configured to be complementary to the configuration of perimeter flange 50. Flat gasket 32 is a rectangular cross-section with flat contacting surfaces to match and seal against the flat contacting surface of protruding surface 54, complementary to the preferred configuration of perimeter flange 50 shown in FIG. 2. Bubble gasket 34 is a flexible gasket with multiple possible faces or surfaces to seal within the various faces and surfaces of inverted surface 52 on perimeter flange 50. Preferably each gasket is continuous around the perimeter of access port 40 so as to further improve the seal although discontinuous pieces may be fused together to accommodate the particular configuration and shape of perimeter flange 50.

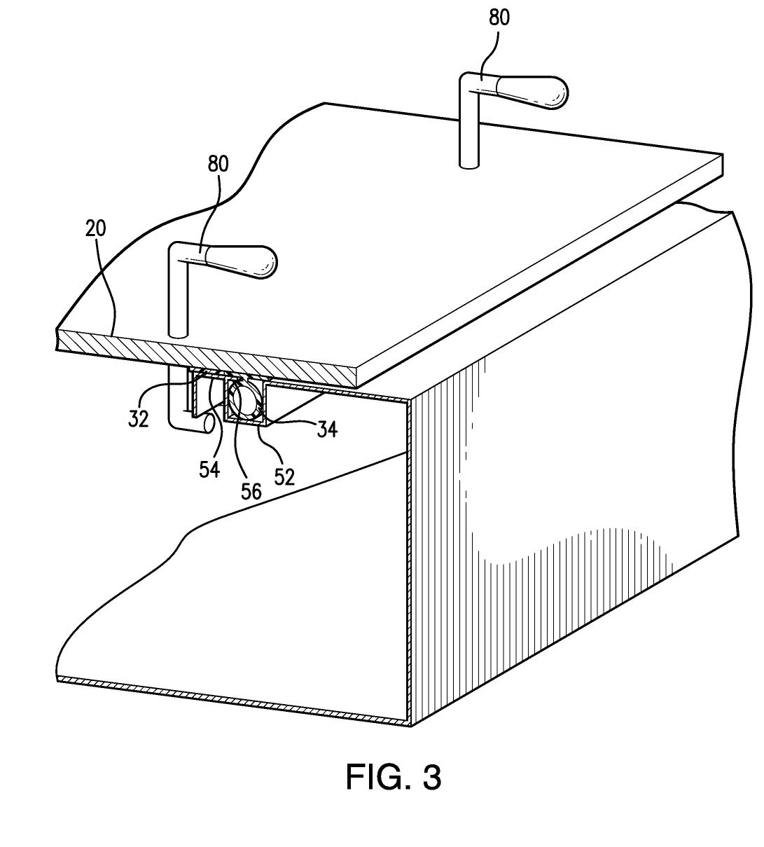

FIG. 3 further illustrates locking lip 56, extending partially into the channel of inverted surface 52 and designed to lock into and provide a further sealing surface around bubble gasket 34. Lip 56 extends and continues the flat contacting surface of protruding surface 54 in the same plane partially into the channel of inverted surface 52. Preferably, locking lip 56 extends from the interior wall of the channel of inverted surface 52. Optionally, a second locking lip 56 may extend from the opposite side of the channel of inverted surface 52 to provide a further sealing surface. Lip 56 is of a complementary shape and extends a complementary distance into the channel to engage bubble gasket 34. Lip 56 extends from about 10% to about 35% of the distance across the channel of inverted surface 52. More than about 35% of the distance may impede bubble gasket 34 from penetrating the channel of inverted surface 52 while less than about 10% does not provide a beneficial amount of additional sealing surface. However, different shapes of bubble gasket 34 may allow for varied distances for lip 56 to extend into the channel of inverted surface 52. When door 20 is closed, bubble gasket 34 flexibly deforms so as to penetrate within inverted surface 52 and engage with lip 56 and inverted surface 52.

In FIG. 1, double gasket assembly 30 uses flat gasket 32 toward the interior of door 20 and bubble gasket 34 toward the exterior of door 20 that are complementary to the configuration shown for perimeter flange 50. While greater than two gaskets may be used with similar units, the drawback of the added expense and bulk of additional gaskets often negates the benefits. The present invention provides equal resistance to ingress of water as demonstrated by passing regulatory requirements using just two gaskets.

The preferred embodiment of the present invention for water resistant outdoor storage cabinet 100 is where the entirety of gasket assembly 30 is affixed to exterior surface 60 or to door 20 with perimeter flange 50 on the opposite member. In the alternative, depending upon the design of water resistant outdoor storage cabinet 100, the elements of gasket assembly 30, flat gasket 32 and bubble gasket 34, may be separated and on separate members. For example, flat gasket 32 may attach to door 20 and bubble gasket 34 may attach to exterior surface 60 of storage cabinet box 10. In this alternative embodiment, inverted surface 52 and protruding surface 54 of perimeter flange 50 would also be separated and complementary in configuration.

The size and shape of the elements of gasket assembly 30 should correspond appropriately to the size and shape used for inverted surface 52 and protruding surface 54, which can vary in depth and height, respectively, from about 0.2 cm to about 5.0 cm, but preferably between about 1 cm and 3 cm deep and the width from 0.2 cm to 5.0 cm across and preferably 1.0 cm-2.0 cm across.

Flat gasket 32 preferably has a rectangular cross-section with flat contacting faces, designed for a high pressure seal preferably constructed of a high density material such as rubber or foam. Preferably it has an approximately rectangular cross-section from about 0.20 cm thick to about 0.50 cm thick and between about 1.0 cm and about 5 cm wide. Flat gasket 32 functions best when in contact between two flat surfaces or edges where there are few imperfections, protrusions or other surface interruptions such as screws, rivets or bolts.

FIG. 1 illustrates an embodiment of the present invention incorporating flat gasket 32, which is interior to bubble gasket 34 in the embodiment shown, in order to correspond to the interior protruding surface 54 of perimeter flange 50. Similarly, bubble gasket 34 corresponds to inverted surface 52 of perimeter flange 50 as shown. Flat gasket 32 is preferably placed interior or inward of bubble gasket 34 such that any water intrusion would first be resisted by bubble gasket 34 before coming in contact with flat gasket 32. The present invention intends to create the longest route possible for water to have to travel in contact with the most sealing surface in order to resist water ingress. To accomplish this, a bubble type and a flat-type gasket are used.

Bubble gasket 34 may have a cross-section of any shape such as round, half-round, square, triangular and the like capable of conforming to the inverted, trough shape used for inverted surface 52. Bubble gasket 34 may be solid or hollow as optimal to be flexible enough to fully seal inverted surface 52 of perimeter flange 50. Preferably bubble gasket 34 is hollow and round in shape as shown by the cross-section in FIG. 2.

The channel of inverted surface 52 can be a full U-shape, V-shape as well as the square bottom shape shown in FIG. 2. The shape of the channel of inverted surface 52 is designed to be most optimal for the shape and design of bubble gasket 34. The channel of inverted surface 52 forms a complete channel with vertical walls on either side of the inverted surface 52.

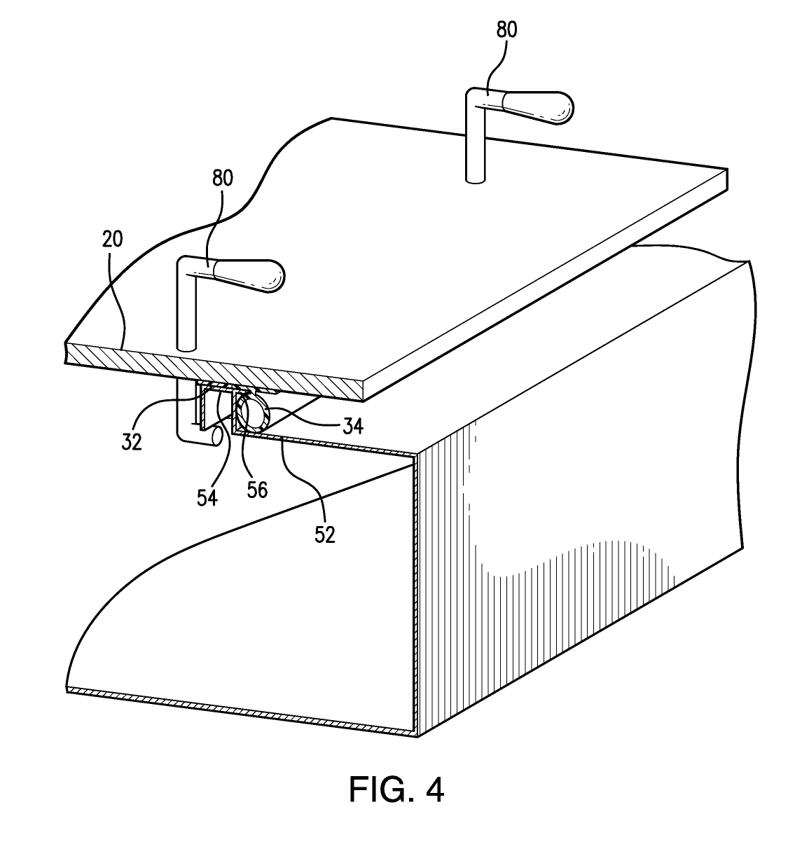

FIG. 4 illustrates a further embodiment of inverted surface 52 providing only a single vertical wall forming an L-shaped channel of inverted surface 52.

Flat gasket 32 preferably has a rectangular cross section as shown in FIG. 2, but it may be square, triangular or other shape with a flat surface contacting the flat surface of protruding surface 54 of perimeter flange 50.

The flat contacting surface of protruding surface 54 can be of any desired width and can either correspond in with to flat gasket 32 or may be more narrow such that flat gasket 32 in the compressed position extends over a vertical wall of protruding surface 54. In a narrow shape of protruding surface 54, it may then take on a semi-circular, triangular or remain a square-shape contacting surface.

Gasket assembly 30, and in particular flat gasket 32, may be designed to require high pressure to compress and seal gasket assembly 30 between the contacting surfaces of door 20 and perimeter flange 50. In practice, flat gasket 32 may compress from about 10% of its relaxed thickness to about 50% of its relaxed thickness.

Bubble gasket 34 is preferably constructed of a soft and flexible material and design. The shape may be such as a U-shape to provide structural flexibility or an enclosed O-shape, for example. The material for bubble gasket 34 is preferably a softer foam or rubber commonly used in these types of gasket materials. The material may have some form of a flexible metal or other structural interior reinforcement to provide additional structural integrity to bubble gasket 34. Bubble gasket 34 is shown in FIG. 2 in its preferred embodiment as an enclosed O-shape adhered to door 20.

Bubble gasket 34 is preferably located exterior of flat gasket 32 and designed to also come in contact with any screws, rivets, troughs, channels or imperfections in the surface of door 20 or storage box 10 or hinge assembly 70. The soft and flexible material and design of bubble gasket 34 forms over the imperfections and seal tightly around such imperfections. A lower pressure may be required to deform bubble gasket 34 than flat gasket 32 so that it may form around imperfections and may compress from about 10% to about 50% of its relaxed thickness and may compress up to about 90% of its thickness in order to seal around imperfections.

Bubble gasket 34 is further designed to not only successfully seal around imperfections, but to snugly fit within the trough or channel of inverted surface 52 that may be formed into exterior surface 60 or door 20 of storage cabinet box 10 providing multiple contacting surfaces for bubble gasket 34 to seal against and provide further resistance to water ingress.

A further embodiment of the present invention may have the attachment location of each member of gasket assembly 30 reversed from the preferred embodiment shown in FIG. 1. Flat gasket 32 may attach to the exterior surface of storage cabinet box 10 and bubble gasket 34 may attach to door 20. In any event, flat gasket 30 is preferably interior to bubble gasket 34 leaving bubble gasket 34 available to cover any screw head, bolts or nuts, rivets or other attaching mechanisms or imperfections that may be present on door 20 or exterior surface 60 of storage cabinet box 10 that would cause the contacting relationship to have a gap allowing water ingress.

Both flat gasket 32 and bubble gasket 34 follow the perimeter portion of access port 40 where door 20 and exterior surface 60 of storage cabinet box 10 are in contacting relation.

Flat gasket 32 and bubble gasket 34 may be of the same or different construction material depending upon the kinds of protrusions and other surfaces on the perimeter portion of door 20 and storage cabinet box 10. A rubber material may be vulcanized to create seamless continuity of gasket assembly 30. A high temperature rubber or silicone or other synthetic material may also provide heat resistance sufficient to withstand extremes in environmental conditions and other regulatory requirements that may be under the NEBs regulations. The construction material for gasket assembly 30 in any event is distinguished as being capable of multiple uses, multiple opening and closings of door 20. The material is not designed merely to be a one use application such as some form of flowable sealant applied before closing door 20 that would then cure or dry to some final and non-releasable form.

Further embodiments of the present invention may have flat gasket 32 and bubble gasket 34 gasket adhered to each other using an adhesive, tape, vulcanization or otherwise adhered together to form an even greater water barrier. If the material of each gasket is compatible, the two gaskets may be vulcanized together.

Gasket assembly 30 may be adhered to door 20 or exterior surface 60 of storage cabinet box 10 with any such standard adhesive that is compatible with the gasket material, the storage cabinet box material and the environmental conditions required for the intended purpose of water resistant outdoor storage cabinet 100 or under NEBS GR-47.

Access port 40 through exterior surface 60 of storage cabinet box 10 may be square, round, oval or other appropriate shape as dictated by the design of storage cabinet box 10 and the water sensitive equipment and apparatus stored within.

Perimeter flange 50 defines the shape and size of access port 40 on exterior surface 60 of storage cabinet box 10. Perimeter flange 50 may be incorporated into exterior surface 60 of storage cabinet box 10 defining access port 40 and may be designed to enhance access to the interior of storage cabinet 10 and the water sensitive contents therein. In the alternative, perimeter flange 50 may be a separate member applied and permanently attached by welding for example to exterior surface 60 of storage cabinet box 10. In the alternative, perimeter flange 50 may be incorporated into door 20 in a similar manner.

Perimeter flange 50 is preferably shaped to enhance the effectiveness of the seal between door 20 and storage cabinet box 10. The perimeter edge of access port 40 in exterior surface 60 or the perimeter edge of door 20 defining perimeter flange 50 may include a rolled edge, a recessed or inverted trough, inverted flat surface, a channel, a U-shaped trough, a V-shaped trough, a flat bottom trough, a concave semi-circular shape, a protruding flat surface, a protruding convex semi-circular shape, protruding triangular shape, or other shape considered optimal to resist intrusion of water into water resistant outdoor storage cabinet 100 or to provide optimal structural rigidity and strength to storage cabinet box 10, and combinations thereof. Perimeter flange 50 preferably incorporates at least two of these perimeter edge elements and more preferably incorporates inverted surface 52 on the exterior of the perimeter edge and protruding surface 54 on the interior of the perimeter edge of perimeter flange 50.

FIG. 2 shows a preferred embodiment of perimeter flange 50 where inverted surface 52 has a flat bottom surface and protruding surface 54 is a flat top surface. Protruding surface 54 in this embodiment is located near the interior edge or is interior to inverted surface 52 on perimeter flange 50. Further embodiments of perimeter flange 50 of the present invention may have inverted surface 52 and protruding surface 54 reversed in orientation.

Perimeter flange 50 is preferably continuous so as to further improve the seal.

Inverted surface 52 and protruding surface 54 can vary in depth or height, respectively, as desired from about 0.2 cm to about 5.0 cm, but preferably between about 1 cm and 3 cm deep and the width from 0.2 cm to 5.0 cm across and preferably 1.0 cm-2.0 cm across.

FIG. 1 shows door 20, designed to removably or releasably obstruct and cover access port 40. The perimeter edge of door 20 should be of a complementary dimension to the perimeter edge of exterior surface 60 defining access port 40 in order to fully cover and come in complete contacting relation with the perimeter edge of exterior surface 60 defining access port 40. When perimeter flange 50 is on door 20 then a complementary perimeter edge is on exterior surface 60 defining access port 40 and when perimeter flange 50 is on the perimeter edge of exterior surface 60 defining access port 40 then the perimeter edge of door 20 shall be of a complementary configuration.

Door 20 may be releasably attached to storage cabinet box 10 by hinge assembly 70 such as a hinge, clamp, latch or other ordinary mechanism for moveably attaching a door, or fully removably attached with locking brackets of any ordinary type in order to remove and reattach door 20. Door 20 is attached so as to come into contacting relation to exterior surface 60 of storage cabinet box 10 along perimeter flange 50 when in a closed position and to allow access to the interior of water resistant outdoor storage cabinet 100 through access port 40 when in an open position. When in the closed position, door 20 may be locked or otherwise secured into position with one or more latch 80. Latch 80 secures door 20 in place and applies sufficient pressure to engage and compress double gasket assembly 30 into a water tight seal against perimeter flange 50.

Door 20 is shown in FIG. 1 attached to storage cabinet box 10 by hinge assembly 70 affixed to door 20 and to exterior surface 60 by rivets creating an uneven surface. Hinge assembly 70 may be attached to exterior surface 60 of storage cabinet box 10 by screws, rivets, bolts or other fastening device. All such fastening devices may create an uneven surface on exterior surface 60 of storage cabinet box 10 or door 20, which may enhance the ability of water to penetrate into water resistant outdoor storage cabinet 100 requiring the added sealing protection provided by the present invention.

Door 20 should be structurally rigid and strong enough to resist warping, twisting, bending or other structural movement that may create gaps or imperfections in the seal between door 20 and exterior surface 60 of storage cabinet box 10 that may promote water ingress to the interior of storage cabinet box 10.

Water ingress is of such substantial concern that it is governed by GR-47, among other regulations, which sets the standards of environmental conditions which a water resistant outdoor storage cabinet must endure to be designated as passing this testing requirement. The double gasket design of the present invention when tested under GR-47 conditions passed.

The above detailed description of exemplary embodiments of the present invention is provided to illustrate the various aspects of the invention, and is not intended to limit the scope of the invention thereto. Persons of ordinary skill in the art will recognize that certain modifications can be made to the described embodiments without departing from the invention. For example, while the above-described embodiments of the invention have been principally described in connection with telecommunications and electrical equipment storage cabinets that are resistant to water ingress under conditions described by GR-47, double gasket systems according to the present invention may also be configured and used to support other objects or equipment requiring stringent levels of resistance to water ingress. All such modifications are intended to be within the scope of the appended claims.

It will be recognized that the above-described invention may be embodied in other specific forms without departing from the spirit or essential characteristics of the disclosure. Thus, it is understood that the invention is not to be limited by the foregoing illustrative details, but rather is to be defined by the appended claim.

What is claimed is:

1. A water resistant outdoor storage cabinet comprising:
a. a storage cabinet box having an exterior surface;
b. at least one continuous perimeter flange defining an access port on the exterior surface of the storage cabinet box;
c. the perimeter flange comprising a protruding surface portion with a locking lip and an inverted surface portion;
d. a door complementary to the access port and removably attached to the exterior surface of the storage cabinet box;
e. a gasket assembly affixed to the door;
f. wherein the perimeter flange and gasket assembly are configured to create a water tight seal when the door is in a closed position and the gasket assembly is in a contacting relation to the perimeter flange.

2. The water resistant outdoor storage cabinet of claim 1 wherein the gasket assembly comprises a first gasket and a second gasket wherein the first gasket is configured to conform to the inverted surface portion of the perimeter flange and the second gasket is configured to conform to the protruding surface portion of the perimeter flange.

3. The water resistant outdoor storage cabinet of claim 2 wherein the first gasket is a bubble gasket and the second gasket is a flat gasket.

4. The water resistant outdoor equipment storage cabinet of claim 1 wherein the cabinet passes NEBS GR-47 testing.

5. The water resistant outdoor equipment storage cabinet of claim 1 the door is held in the closed position by a latch assembly.

6. The water resistant outdoor equipment storage cabinet of claim 1 wherein the door is removably attached to the exterior surface by a hinge assembly.

7. The water resistant outdoor equipment storage cabinet of claim 1 wherein the inverted surface portion of the perimeter flange is a U-shape.

8. The water resistant outdoor equipment storage cabinet of claim 1 wherein the inverted surface portion of the perimeter flange is a V-shape.

9. The water resistant outdoor equipment storage cabinet of claim 1 wherein the first and second gasket are comprised of a flexible rubber.

10. A water resistant outdoor equipment storage cabinet comprising:
a. a storage cabinet box having an exterior surface with an access port;
b. a door defined by a perimeter flange configured to cover the access port;
c. a gasket assembly adhered to the exterior surface of the storage cabinet box; and
d. wherein the perimeter flange and gasket assembly form a water tight seal when the door is in a closed position sufficient to pass NEBS GR-47 testing.
